(19) United States
(12) Patent Application Publication
(10) Pub. No.: US 2025/0038144 A1
(43) Pub. Date: Jan. 30, 2025

(54) CONDUCTIVE PILLAR IN A SEMICONDUCTOR PACKAGE AND ASSOCIATED MANUFACTURING METHOD

(71) Applicant: Chengdu Monolithic Power Systems Co., Ltd., Chengdu (CN)

(72) Inventors: Heng Li, Chengdu (CN); Ze-Qiang Yao, Santa Clara, CA (US); Jiyan Peng, Chengdu (CN); Yanxin Wang, Chengdu (CN)

(21) Appl. No.: 18/781,418

(22) Filed: Jul. 23, 2024

(30) Foreign Application Priority Data
Jul. 24, 2023 (CN) 202310913002.9

(51) Int. Cl. H01L 23/00; H01L 23/498

(52) U.S. Cl. CPC H01L 24/13; H01L 24/11; H01L 23/498; H01L 24/16; H01L 2224/1147; H01L 2224/13015; H01L 2224/16145; H01L 2224/16221

(57) ABSTRACT

The conductive pillar in a semiconductor package has a gear-shaped top surface. The gear-shaped top surface has a plurality of protrusions distributed on the periphery of the gear-shaped top surface. Contour lines of each of the plurality of protrusions includes a smooth curve that bulges towards the space outside the conductive pillar. The conductive pillar can be defined by the space traversed by the gear-shaped top surface as it moves a certain distance in a direction perpendicular to the gear-shaped top surface. The conductive pillar can effectively enhance the adhesion between lateral surfaces of the conductive pillar and insulating materials.

### CROSS-REFERENCE TO RELATED APPLICATIONS

This application claims the benefit of Chinese Application No. 202310913002.9 filed on Jul. 24, 2023 and incorporated herein by reference.

### TECHNICAL FIELD

Embodiments of the present invention relate to conductive structure that may be used for semiconductor packaging, and more particularly but not exclusively, relate to conductive pillars, a manufacturing method thereof and a photomask used in the manufacturing method.

### BACKGROUND OF THE INVENTION

Conductive pillars are extensively utilized in semiconductor package to establish electrical interconnections between chips, between a chip and a substrate, and between substrates. The choice of materials for these pillars could be copper, gold or other metal. Conductive pillars are often surrounded by other materials, such as insulating underfill, encapsulant materials, and so on. Ideally, this kind of materials, for example, encapsulant materials should tightly adhere to lateral surfaces of the conductive pillar. However, in thermal cycling tests or stress tests, an interface between the encapsulant materials and the conductive pillars is susceptible to stress, which may lead to gaps forming between the encapsulant materials and the lateral surfaces of the conductive pillar, and may even cause the encapsulant materials to delaminate from the lateral surfaces of the conductive pillar.

### SUMMARY OF THE INVENTION

Embodiments of the present invention are directed to a conductive pillar. The conductive pillar has a gear-shaped top surface. The gear-shaped top surface has a plurality of protrusions distributed along the periphery of it. Contour lines of each of the plurality of protrusion has a smooth curve that bulges towards the space outside the conductive pillar.

Embodiments of the present invention are directed to a method for manufacturing the conductive pillar. The method have steps of providing a chip or a substrate and forming a photoresist layer on the surface of the chip or substrate. The method also have steps of providing a photomask that carries a gear-shaped pattern, exposing the photoresist layer using the photomask and developing the photoresist layer to form an opening. In this proposed method, the gear-shaped pattern carried on the photomask has a plurality of protrusions distributed along the periphery of the gear-shaped pattern. Contour lines of each of the plurality of protrusions has a smooth curve that bulges towards the space outside the gear-shaped pattern.

Embodiments of the present invention are directed to a photomask configured to be used to manufacturing a conductive pillar. The photomask has a transparent part which allows light to pass through and an opaque part which blocks the light. Either the transparent part or the opaque part of the photomask has a gear-shaped pattern. The gear-shaped pattern has a plurality of protrusions distributed along the periphery of it. Contour lines of each of the plurality of protrusions has a smooth curve that bulges towards the space outside the gear-shaped pattern.

### BRIEF DESCRIPTION OF DRAWINGS

For a better understanding of the invention, embodiments of the invention will be described in accordance with the following drawings, which are used for illustrative purpose only. The drawings illustrate only some of the features in an embodiment. It should be understood that the drawings are not necessarily to scale. Like elements are provided with like reference numerals in different appended drawings.

FIG. 1 is a cross-section view illustrating a semiconductor package in accordance with an example embodiment of the present disclosure.

FIG. 2 (a) is a schematic diagram of a conductive pillar in accordance with an example embodiment of the present disclosure,

FIG. 2 (b) is a schematic diagram of a regular cylinder pillar.

FIG. 3 is a schematic diagram of a gear-shaped top surface of the conductive pillar in accordance with an example embodiment of the present disclosure.

FIG. 4 (a)˜FIG. 4 (c) are schematic diagrams of some other gear-shaped top surfaces in accordance with some example embodiments of the present disclosure.

FIG. 5 is a schematic diagram of lateral surfaces of the conductive pillar in accordance with an example embodiment of the present disclosure.

FIG. 6 is a schematic diagram of the lateral surfaces of the conductive pillar in accordance with an example embodiment of the present disclosure.

FIG. 7 is a schematic diagram of the lateral surfaces of the conductive pillar in accordance with an example embodiment of the present disclosure.

FIG. 8 is a schematic diagram of a manufacturing method of the conductive pillar in accordance with an example embodiment of the present disclosure.

FIG. 9 is a schematic diagram of a photomask for manufacturing the conductive pillar in accordance with an example embodiment of the present disclosure.

### DETAILED DESCRIPTION OF THE INVENTION

Detailed description of the embodiments is provided merely to give examples and not intended to be limiting. Plenty of details are provided to assist the reader in gaining a comprehensive understanding of the present invention. However, many other ways of implementing the disclosure of this application described herein will be apparent. Description of materials and methods that are known in the art may not be addressed in this disclosure for simplicity.

Throughout the specification and claims, the articles “a,” “an,” and “the” are intended to include the plural forms as well, unless the context clearly indicates otherwise. These phases “one embodiment”, “an embodiment”, “an example” and “examples” are not necessarily directed to the same embodiment or example. Furthermore, the features, structures, or characteristics may be combined in one or more embodiments or examples.

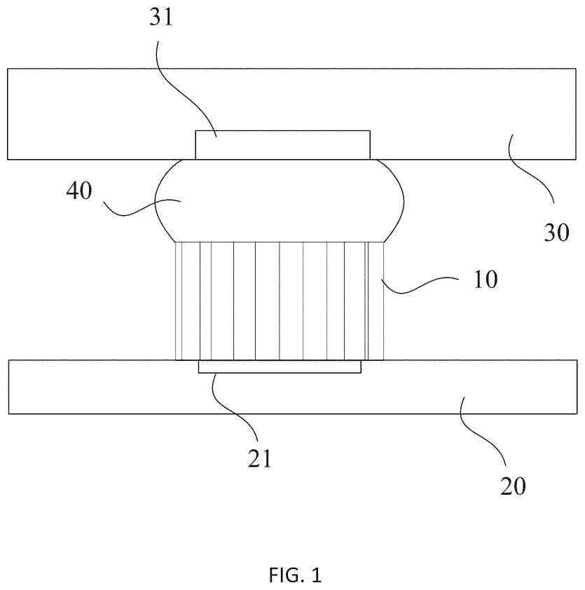

Referring to FIG. 1, a semiconductor package having a chip 20 and a substrate 30 is provided. An upper surface of the chip 20 has a first conductive pad 21, a lower surface of the substrate 30 has a second conductive pad 31, and a conductive pillar 10 is arranged between the first conductive pad 21 and the second conductive pad 31. In one embodiment, solder 40 is placed between the conductive pillar 10 and the second conductive pad 31. In one embodiment, the substrate 30 could be replaced by another chip, so that the conductive pillar 10 is arranged between two stacked chips. In another embodiment, the chip 20 could be replaced by another substrate. Thus, the conductive pillar 10 is set between two stacked substrates.

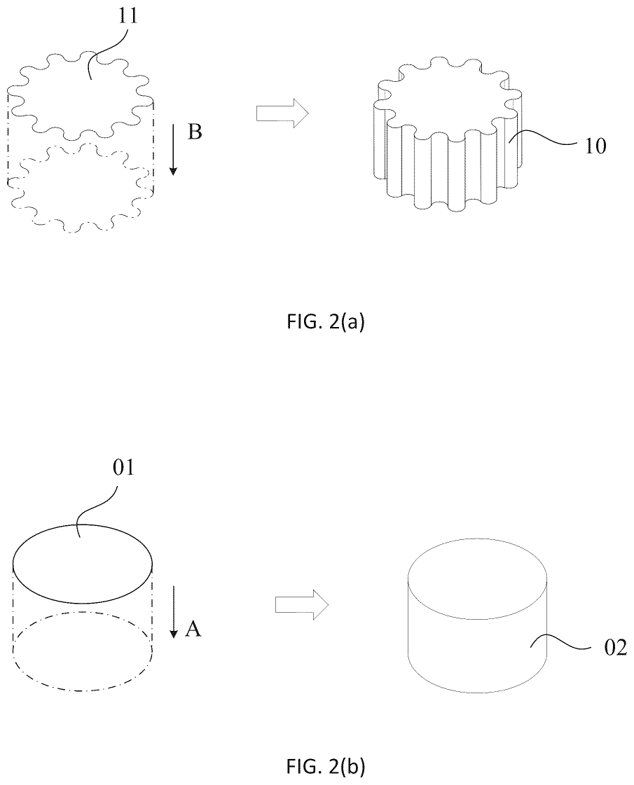

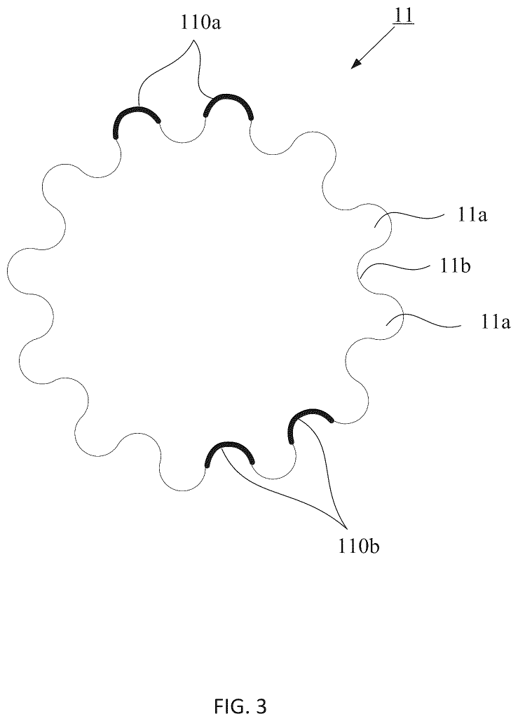

As illustrated in FIG. 2 (a), the conductive pillar 10 in accordance with an example embodiment of this disclosure is generally cylindrical in shape, but it has significant differences from a regular cylinder pillar which is shown in FIG. 2 (b). More specifically, referring to the regular cylinder pillar 02 shown in FIG. 2 (b), the regular cylinder pillar 02 could be defined as follows: taking a circle as a top surface 01, and moving a certain distance along the direction perpendicular to this top surface 01 (i.e., a direction of arrow A in FIG. 2 (b)), then a space traversed generates the regular cylinder pillar 02. While referring to the conductive pillar 10 in accordance with an example embodiment of this disclosure as shown in FIG. 2 (a), the conductive pillar 10 could be defined as follows: taking a gear-shaped top surface 11 as the top surface, and moving a certain distance along the direction perpendicular to the gear-shaped top surface 11 (i.e., a direction of arrow B in FIG. 2 (a)), then a space traversed generates the conductive pillar 10.

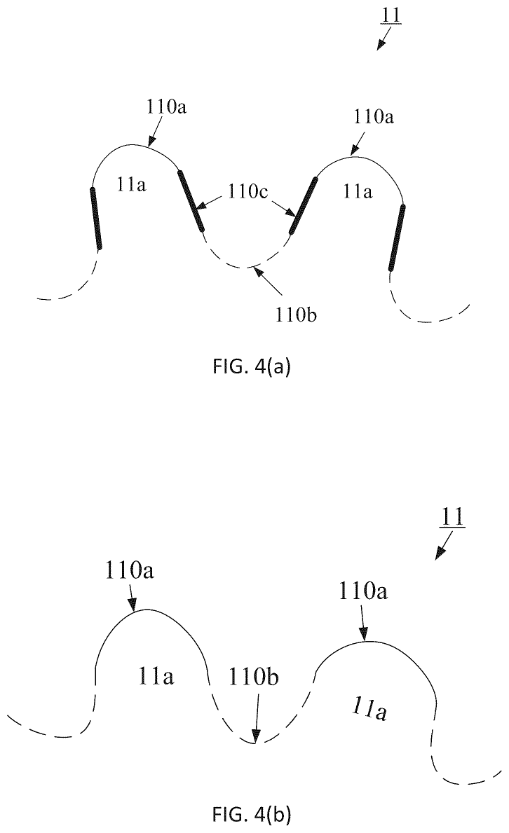

Referring to FIG. 3, in one embodiment of this disclosure, the gear-shaped top surface 11 may have a plurality of protrusions 11a distributed along periphery of the gear-shaped top surface 11. Contour lines of each protrusion 11a has a smooth curve 110a that bulges towards the space outside the gear-shaped top surface 11. This gear-shaped top surface 11 also has a plurality of connecting portions 11b, which are situated between two adjacent protrusions 11a. Contour lines of one connecting portion 11b has a smooth curve 110b that recedes towards the space within the gear-shaped top surface 11.

Although in the exemplary embodiment shown in FIG. 3, the plurality of protrusions 11a are illustrated as being the same and evenly distributed around the periphery of the gear-shaped top surface 11, the present disclosure is not limited to this. In various embodiments of the present disclosure, the plurality of protrusions 11a of the gear-shaped top surface 11 may have different shapes, meaning that the smooth curves 110a of the contour lines of each of the plurality of protrusions 11a can vary. Although the plurality of connecting portions 11b in FIG. 3 are shown of the same shape and evenly distributed, the present disclosure is not limited to this. The plurality of connecting portions 11b can also have different shapes, meaning that the smooth curves 110b of the contour lines of each of the plurality of connecting portions 11b can vary. In various embodiments of the present application, the plurality of protrusions 11a may be arranged in a non-uniform distribution, and also, the plurality of connecting portions 11b may be arranged in a non-uniform distribution.

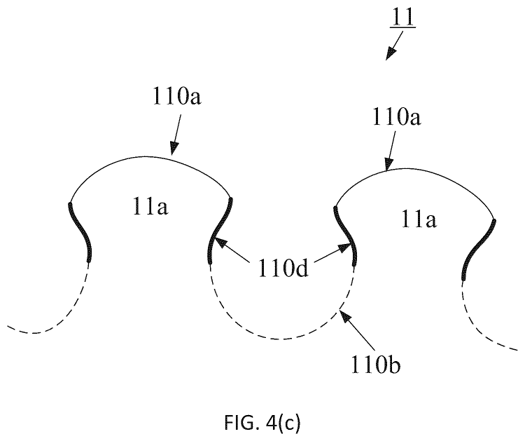

FIG. 4 (a)˜ FIG. 4 (c) illustratively show some other gear-shaped top surfaces 11 of this disclosure by displaying a close-up view that includes two adjacent protrusions 11a. In the embodiment shown in FIG. 4 (a), the smooth curve 110a and the smooth curve 110b of the contour lines of the protrusions 11a are connected by a straight-line segment 110c. For clarity, different line styles are used in FIG. 4 (a) to represent the smooth curves 110a, the smooth curve 110b and the straight-line segment 110c. In the embodiment shown in FIG. 4 (b), the contour lines of the gear-shaped top surface 11 is composed of the smooth curves 110a and the smooth curve 110b. In the embodiment shown in FIG. 4 (c), the smooth curve 110a and the smooth curve 110b are connected by another smooth curve 110d. These examples shown in FIG. 4 (a)˜FIG. 4 (c) merely show some examples. Other gear-shaped top surfaces 11 that are not shown here but have protrusions 11a that bulges towards the space outside the gear-shaped top surface 11, and/or have connecting portions 11b that recedes towards the space within the gear-shaped top surface 11, are also within the scope of protection of this disclosure.

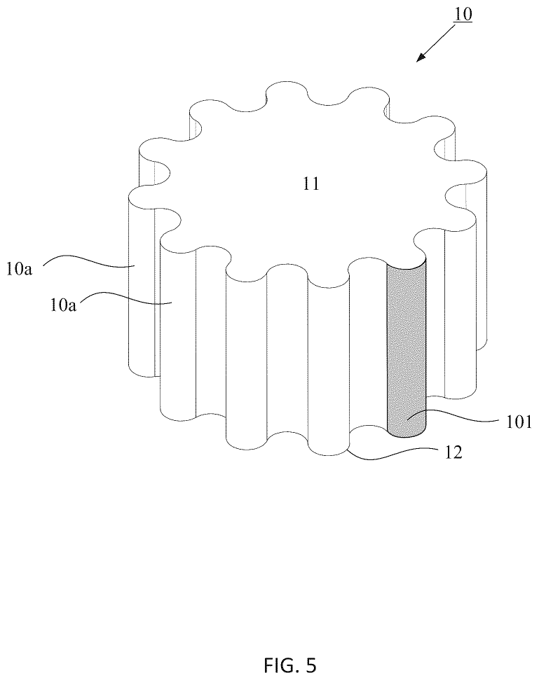

As mentioned before, the shape of the conductive pillar 10 corresponds to the space traversed by the gear-shaped top surface 11 as it moves. Therefore, as shown in FIG. 5, a plurality of rib-like protrusions 10a on lateral surfaces of the conductive pillar 10 correspond to the space traversed by the protrusions 11a as they move. These rib-like protrusions 10a bulge towards the space outside the conductive pillar 10. Each of the plurality of rib-like protrusion 10a has a smooth curved surface 101 that bulges towards the space outside the conductive pillar 10. Each of the plurality of rib-like protrusions 10a extends from the gear-shaped top surface 11 of the conductive pillar 10 to a bottom surface 12, with its extension direction perpendicular to the gear-shaped top surface 11.

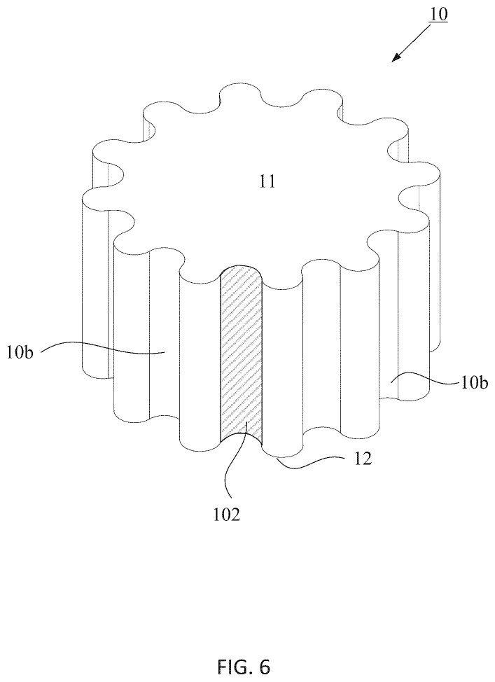

Similarly, as shown in FIG. 6, a plurality of strip cavities 10b on the lateral surfaces of the conductive pillar 10 correspond to the space traversed by the connecting portions 11b as they move. The plurality of strip cavities 10b are distributed on the lateral surfaces of the conductive pillar 10 and recede towards the space within the conductive pillar 10. Each of the plurality of strip cavities 10b has a smooth curved surface 102 that recedes towards the space within the conductive pillar 10. Each of the plurality of strip cavities 10b extends from the gear-shaped top surface 11 to the bottom surface 12 of the conductive pillar 10, and its extension direction is perpendicular to the gear-shaped top surface 11.

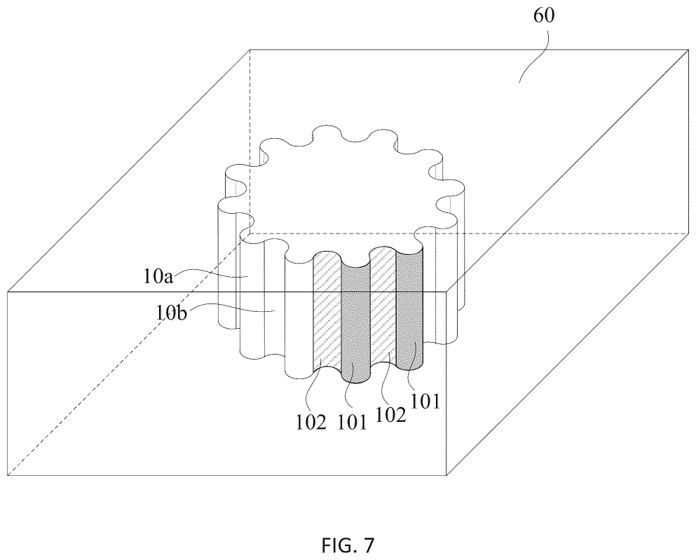

In one embodiment, the conductive pillar 10 has a shape resembling a Roman column. As shown in FIG. 7, the plurality of rib-like protrusions 10a and the plurality of strip cavities 10b are alternately arranged on the lateral surfaces of the conductive pillar 10. In one embodiment, the lateral surfaces of the conductive pillar 10 is composed only of alternating smooth curved surfaces 101 that bulge towards the space outside the conductive pillar 10 and smooth curved surfaces 102 that recede towards the space within the conductive pillar 10. As previously described, the gear-shaped top surface 11 has various possible implementations, and the arrangement of a plurality of protrusions 11a includes but is not limited to the examples shown in FIGS. 4 (a)-(c). Accordingly, the lateral surfaces of the conductive pillar 10 may also has various possible implementations. As long as the lateral surfaces includes a plurality of rib-like protrusions 10a that bulge towards the space outside the conductive pillar and/or a plurality of strip cavities 10b that recede towards the space within the conductive pillar 10, it is also within the scope of protection of this application.

Referring to FIG. 7, when insulating material 60 is configured to a space outside the conductive pillar 10 and is adequately filled into the plurality of strip cavities 10b, an interface between the insulating material 60 and the conductive pillar 10 could be a surface having alternating pattern of concave and convex surfaces. Compared to the regular cylinder pillar 02, the structure of the conductive pillar 10 as disclosed here can significantly increase the interfacial area between the insulating material 60 and the conductive pillar 10. Furthermore, the structure of the conductive pillar 10 could change a fracture instability propagation mode in thermal cycling tests or stress tests. Based on fracture mechanics, if a gap between the regular cylinder pillar 02 and the insulating material 60 is presented, the fracture instability propagation mode is mainly opening-mode instability propagation, which requires a relatively low amount of energy for propagation. In other words, a comparatively low stress level could induce delamination of the insulating material 60 at the interface between the insulating material 60 and the regular cylinder pillar 02, leading to formation of cracks. By contrast, if there is a gap between the conductive pillar 10 and the insulating material 60, the fracture instability propagation mode includes both opening-mode instability propagation and sliding-mode instability propagation, with the sliding-mode instability propagation requiring times the energy of the opening-mode instability propagation. Thus, only a higher level of stress could then possibly cause damage to the interface between the insulating material 60 and the conductive pillar 10. Furthermore, to accommodate the specific application environment and the stress conditions present, the fracture instability propagation mode in various regions of the conductive pillar could be designed and moderated. As mentioned above, both the plurality of protrusions 11a and the plurality of connecting portions 11b can have different shapes, the plurality of protrusions 11a may be arranged in a non-uniform distribution, and also, the plurality of connecting portions 11b may be arranged in a non-uniform distribution. So, the fracture instability propagation mode across different regions of the conductive pillar can be precisely controlled by employing a sophisticated and adaptable design approach for the smooth curves 110a of the protrusions 11a and/or the smooth curves 110b of the connecting portions 11b. The structure of the conductive pillar 10 provides design flexibility that allows the conductive pillar 10 to accommodate the demands of various stress distribution conditions.

In one embodiment of this disclosure, the number of the plurality of protrusions 11a on the gear-shaped top surface 11 must be six or more. That is to say, the number of the plurality of rib-like protrusions 10a on the conductive pillar 10 must be six or more. As shown in FIG. 1, in some embodiments, the solder 40 is typically applied on the top surface of the conductive pillar 10. The solder 40 is formed by a low-melting-point material that possesses a certain degree of fluidity during the reflow process. Setting the number of the plurality of rib-like protrusions 10b to be six or more can effectively retain the solder 40 at the top of the conductive pillar 10 during the reflow process, preventing the solder 40 from flowing down the side walls of the conductive pillar 10.

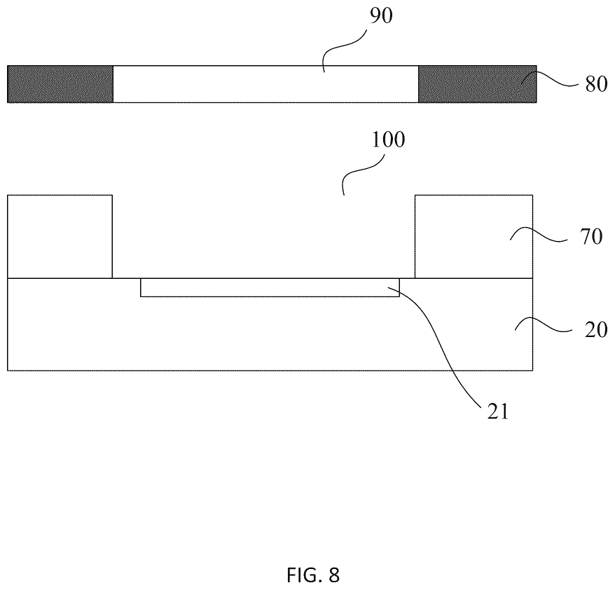

Referring to FIG. 8, this disclosure also provides a method for manufacturing a conductive pillar. The method may have following steps: providing a chip 20 or a substrate 30; forming a photoresist layer 70 on the surface of the chip 20 or substrate 30; providing a photomask 80 that carries a gear-shaped pattern 90; exposing the photoresist layer 70 using the photomask 80; and developing the photoresist layer 70 to form an opening 100. In this proposed method, the gear-shaped pattern 90 carried on the photomask 80 matches exactly the shape of the gear-shaped top surface 11. Therefore, after exposure and development, the shape of the opening 100 is that of the space traversed by moving a certain distance in a direction perpendicular to the top surface of the gear-shaped top surface 11.

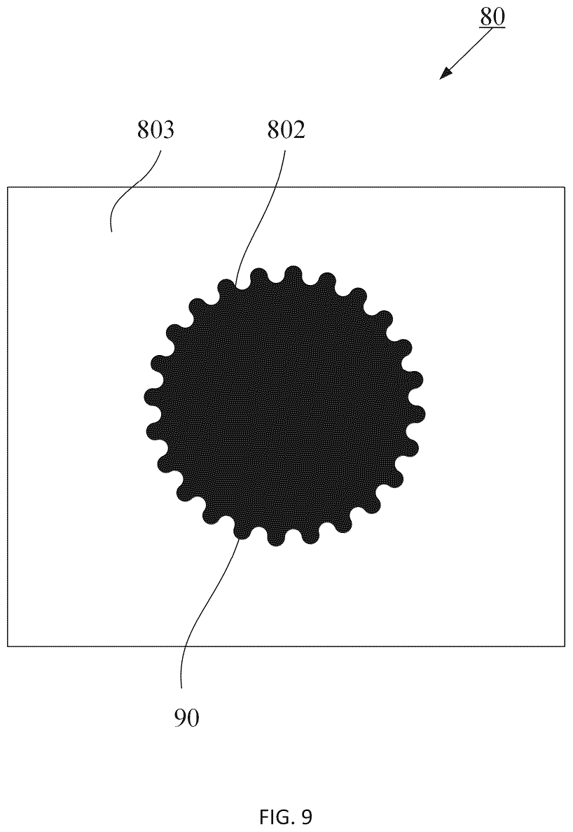

The photomask 80 includes an opaque part 802 and a transparent part 803. The transparent part 803 allows light used in the exposure process to pass through, while the opaque part 802 blocks the light from the exposure process. In the embodiment shown in FIG. 9, the photomask 80 carrying the gear-shaped pattern 90 refers to the opaque part 802 being the gear-shaped pattern 90. In other embodiments, the photomask 80 carrying the gear-shaped pattern 90 refers to the transparent part 803 being the gear-shaped pattern 90.

By using the manufacturing method provided in this application, the conductive pillar 10 could be easily formed. Compared to regular cylinder pillar 02, the conductive pillar 10 formed by this manufacturing method can increase the interfacial area between the insulating material and the conductive pillar. Moreover, the fracture instability propagation mode across different regions of the conductive pillar can be precisely controlled, which is good to improving the adhesion between the lateral surfaces of the conductive pillar 10 and the insulating material 60.

While some embodiments of the present invention have been described in detail above, it should be understood, of course, these embodiments are for exemplary illustration only and are not intended to limit the scope of the present invention. Various modifications are contemplated, and they obviously will be resorted to by those skilled in the art without departing from the spirit and the scope of the invention.

1. A conductive pillar in a semiconductor package, comprising:
a gear-shaped top surface having a plurality of protrusions distributed along the periphery of the gear-shaped top surface, wherein contour lines of each of the plurality of protrusion has a smooth curve that bulges towards the space outside the conductive pillar.

2. The conductive pillar of claim 1, wherein the gear-shaped top surface further has a plurality of connecting portions, wherein each of the plurality of connecting portion is situated between two adjacent protrusions, and contour lines of each of the plurality of connecting portion has a smooth curve that recedes towards the space within the conductive pillar.

3. The conductive pillar of claim 2, wherein each of the plurality of connecting portion is situated between any two adjacent protrusions.

4. The conductive pillar of claim 1, wherein the number of the plurality of protrusions is six or more.

5. The conductive pillar of claim 1, a shape of the conductive pillar is that of a space traversed by the gear-shaped top surface as it moves a certain distance in a direction perpendicular to the gear-shaped top surface.

6. The conductive pillar of claim 1, wherein the conductive pillar further has a plurality of rib-like protrusions distributed on lateral surfaces of the conductive pillar, wherein each of the plurality of rib-like protrusions extends from the gear-shaped top surface to a bottom surface of the conductive pillar, with its extension direction perpendicular to the gear-shaped top surface.

7. The conductive pillar of claim 6, wherein the number of the plurality of rib-like protrusions is six or more.

8. The conductive pillar of claim 6, wherein each of the plurality of rib-like protrusions has a smooth curved surface that bulges towards the space outside the conductive pillar.

9. The conductive pillar of claim 1, wherein the conductive pillar further has a plurality of strip cavities distributed on lateral surfaces of the conductive pillar, wherein each of the plurality of strip cavities extends from the gear-shaped top surface to a bottom surface of the conductive pillar, with its extension direction perpendicular to the gear-shaped top surface.

10. The conductive pillar of claim 9, wherein each of the plurality of strip like cavity has a smooth curved surface that recedes towards the space within the conductive pillar.

11. The conductive pillar of claim 1, wherein the conductive pillar further has a plurality of rib-like protrusions and a plurality of strip cavities, the plurality of rib-like protrusions and the plurality of strip cavities are alternately distributed on lateral surfaces of the conductive pillar, wherein each of the plurality of rib-like protrusions extends from the gear-shaped top surface to a bottom surface of the conductive pillar, with its extension direction perpendicular to the gear-shaped top surface and wherein each of the plurality of strip cavities extends from the gear-shaped top surface to the bottom surface of the conductive pillar, with its extension direction perpendicular to the gear-shaped top surface.

12. The conductive pillar of claim 11, wherein each of the plurality of rib-like protrusion has a smooth curved surface that bulges towards the space outside the conductive pillar and wherein each of the plurality of strip like cavities has a smooth curved surface that recedes towards the space within the conductive pillar, the lateral surfaces of the conductive pillar is composed only of alternating smooth curved surfaces that bulge towards the space outside the conductive pillar and smooth curved surfaces that recede towards the space within the conductive pillar.

13. A method for manufacturing a conductive pillar in a semiconductor package, comprising:
providing a chip or a substrate;
forming a photoresist layer on a surface of the chip or on a surface of the substrate;
providing a photomask which carries a gear-shaped pattern;
exposing the photoresist layer using the photomask; and
developing the photoresist layer to form an opening;
wherein the gear-shaped pattern carried on the photomask has a plurality of protrusions distributed along the periphery of the gear-shaped pattern, wherein contour lines of each of the plurality of protrusions has a smooth curve that bulges towards the space outside the gear-shaped pattern.

14. The method of claim 13, wherein the gear-shaped pattern further has a plurality of connecting portions, wherein each of the plurality of connecting portions is situated between two adjacent protrusions, and contour lines of each of the plurality of connecting portions has a smooth curve that recedes towards the space within the gear-shaped pattern.

15. The method of claim 14, wherein each of the plurality of connecting portions is situated between any two adjacent protrusions.

16. The method of claim 14, wherein the number of plurality of protrusions is six or more.

17. A semiconductor package, comprising:
a chip having a first conductive pad on its surface;
a substrate having a second conductive pad on its surface; and
a conductive pillar configured between the first conductive pad and the second conductive pad;
wherein the conductive pillar comprises a gear-shaped top surface having a plurality of protrusions distributed along the periphery of the gear-shaped top surface, wherein contour lines of each of the plurality of protrusion has a smooth curve that bulges towards the space outside the conductive pillar.

18. The semiconductor package of claim 17, the semiconductor package further comprises insulating material arranged to a space outside the conductive pillar.

19. The semiconductor package of claim 17, wherein the conductive pillar further has a plurality of strip cavities distributed on lateral surfaces of the conductive pillar, wherein each of the plurality of strip cavities extends from the gear-shaped top surface to a bottom surface of the conductive pillar, with its extension direction perpendicular to the gear-shaped top surface.

20. The semiconductor package of claim 19, the semiconductor package further comprises insulating material arranged to a space outside the conductive pillar, wherein the plurality of strip cavities are filled with the insulating material.
